(19) United States
(12) Patent Application Publication
(10) Pub. No.: US 2008/0142249 A1
(43) Pub. Date: Jun. 19, 2008

(54) SELECTIVE SURFACE ROUGHNESS FOR HIGH SPEED SIGNALING

(75) Inventors: Bruce J. Chamberlin, Vestal, NY (US); Daniel N. De Araujo, Cedar Park, TX (US); Erica E. Jasper Gant, Austin, TX (US); Bhyrav M. Mutnury, Austin, TX (US)

Correspondence Address: SAWYER LAW GROUP LLP, PO BOX 51418, PALO ALTO, CA, 94303, US

(73) Assignee: International Business Machines Corporation, Armonk, NY (US)

(21) Appl. No.: 11/610,470

(22) Filed: Dec. 13, 2006

(51) Int. Cl. H05K 1/02; H05K 3/00

(52) U.S. Cl. 174/255; 29/846

(57) ABSTRACT

A circuit board and a method for fabricating a circuit board are provided. The circuit board includes a dielectric core comprising a first surface and a second surface and a conductive layer comprising a first surface and a second surface. The first surface of the conductive layer is coupled to the second surface of the dielectric core. A first region of the second surface of the conductive layer is smooth and a second region of the second surface of the conductive layer is rough. The first region of the second surface of the conductive layer is operable to support high speed signaling and the second region of the second surface of the conductive layer is operable to support non-high speed signaling.

### FIELD OF THE INVENTION

The present invention relates generally to circuit boards.

### BACKGROUND OF THE INVENTION

Electronic components, such as processors, controllers, and other semiconductor devices, can be mounted on circuit boards that include pathways (also called traces) to interconnect the electronic components. A circuit board, sometimes referred to as a printed circuit board (PCB) or a printed wiring board (PWB), comprises one or more layers of conductive material (e.g., copper) separated and supported by insulating material (e.g., fiberglass-epoxy resin).

To promote adhesion between a conductive layer and an insulating layer in a circuit board, the conductive layer is often roughened to ensure that the adhesion satisfies manufacturing and reliability requirements. A roughened conductive layer, however, results in higher losses during high speed signaling. Hence, there is a conflict between reducing high speed signaling loss, which requires a smoother conductive layer, and ensuring sufficient adhesion between conductive and insulating layers, which requires a rougher conductive layer.

### SUMMARY OF THE INVENTION

A circuit board and a method for fabricating a circuit board are provided. The circuit board includes a dielectric core comprising a first surface and a second surface and a conductive layer comprising a first surface and a second surface. The first surface of the conductive layer is coupled to the second surface of the dielectric core. A first region of the second surface of the conductive layer is smooth and a second region of the second surface of the conductive layer is rough. The first region of the second surface of the conductive layer is operable to support high speed signaling and the second region of the second surface of the conductive layer is operable to support non-high speed signaling.

The method includes providing a dielectric core comprising a first surface and a second surface, providing a conductive layer comprising a first surface and a second surface, the second surface of the conductive layer being smooth, coupling the first surface of the conductive layer to the secnd surface of the dielectric core, masking a first region of the second surface of the conductive layer, and roughening a second region of the second surface of the conductive layer, wherein the first region of the second surface of the conductive layer remains smooth, the first region of the second surface of the conductive layer being operable to support high speed signaling and the second region of the second surface of the conductive layer being operable to support non-high speed signaling.

### BRIEF DESCRIPTION OF THE DRAWINGS

FIG. 1 depicts a sample circuit board.

FIG. 2 is a flowchart of a method for fabricating a circuit board according to an implementation of the invention.

FIG. 3 shows a modified version of the sample circuit board depicted in FIG. 1.

FIG. 4 illustrates a top-down view of a circuit board according to an implementation of the invention.

FIGS. 5-6 illustrate perspective views of circuit boards according to various implementations of the invention.

FIG. 7 depicts a flowchart of a method for fabricating a circuit board according to an implementation of the invention

FIGS. 8A-8F are cross-sectional views of a circuit board at various stages during fabrication according to an implementation of the invention.

FIG. 9 shows a cross-sectional view of various layers of a circuit board according to an implementation of the invention.

### DETAILED DESCRIPTION

The present invention relates generally to circuit boards. The following description is presented to enable one of ordinary skill in the art to make and use the invention and is provided in the context of a patent application and its requirements. The present invention is not intended to be limited to the implementations shown, but is to be accorded the widest scope consistent with the principles and features described herein.

Circuit boards are used to mechanically support and electrically interconnect multiple electronic components, such as processors, controllers, and other semiconductor devices. A circuit board, which can be rigid or flexible, includes one or more layers of conductive material separated by insulating material. To interconnect electronic components, pathways (also referred to as traces, lines, or nets) can be formed in a conductive layer through, for instance, chemical etching or laser ablation.

The layers of conductive and insulating material are usually coupled together through, for instance, lamination (i.e., glued together with heat, pressure, and/or vacuum). To ensure that the adhesion between a conductive layer and an insulating layer satisfies manufacturing, assembly, and usage requirements, which are typically measured in terms of peel strength (i.e., the amount of strength required to separate a conductive layer from an insulating layer), a surface of the conductive layer to be coupled to a surface of the insulating layer can be roughened using, for example, a chemical or laser process.

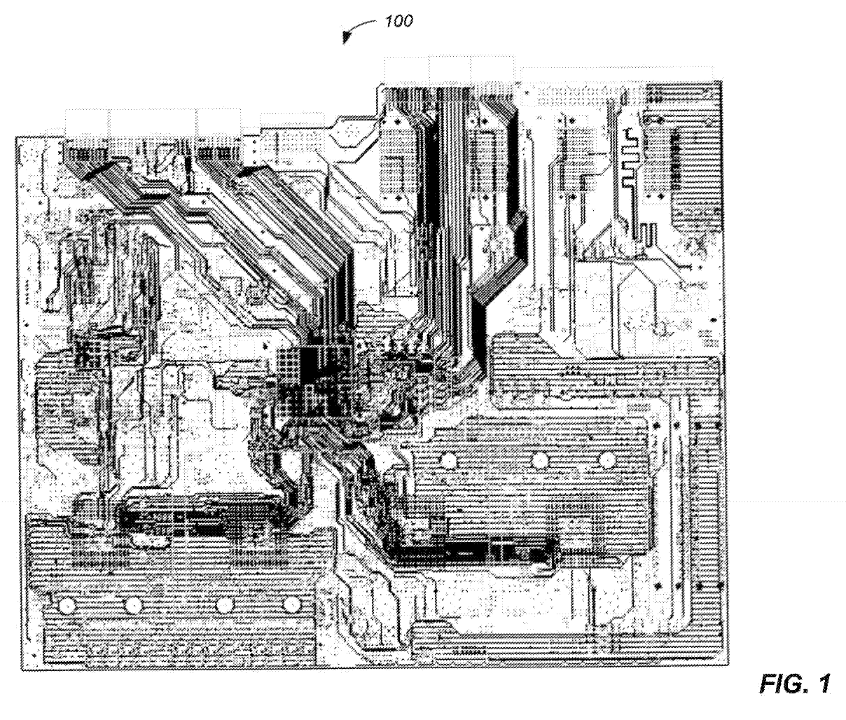

Depicted in FIG. 1 is a sample circuit board 100. In FIG. 1, all traces on sample circuit board 100 have been uniformly roughened, which are depicted as darkened lines. Although uniform surface roughness provides better adhesion between conductive and insulating layers, it also results in a greater amount of loss as the speed (i.e., frequency) of signaling in circuit boards increase. Thus, there needs to be a balance between having sufficient adhesion and not impeding electrical performance.

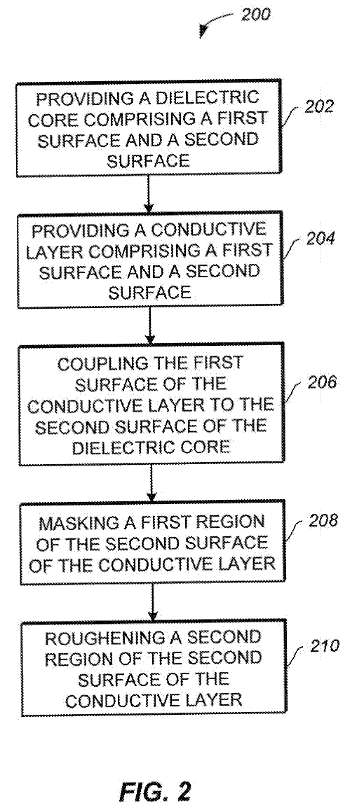

FIG. 2 illustrates a process 200 for fabricating a circuit board according to an implementation of the invention. At 202, a dielectric core comprising a first surface and a second surface are provided. The dielectric core may be a fiberglass-epoxy resin, Teflon®, aluminum, polyimide, or other suitable material. The material used depends on the function of the circuit board as some materials perform better in some environments than others (e.g., heat and humidity), some materials are more suitable for particular manufacturing processes (e.g., hole punching), and other materials are chosen for electrical properties (e.g., permittivity). In one implementation, the first surface is opposite the second surface.

A conductive layer comprising a first surface and a second surface is provided at 204. The second surface of the conductive layer is smooth. In one implementation, the conductive layer is a layer of copper foil. At 206, the first surface of the conductive layer is coupled to the second surface of the dielectric core. A first region of the second surface of the conductive layer is masked at 208 and a second region of the second surface of the conductive layer is roughened at 210. As a result of the masking, the first region of the second surface of the conductive layer remains smooth.

The first region of the second surface of the conductive layer is operable to support high speed signaling and the second region of the second surface of the conductive layer is operable to support non-high speed signaling. In one implementation, high speed signaling is signaling at or above 500 Megahertz (MHz).

By selectively roughening a conductive layer in a circuit board based on location of high speed signal traces, sufficient adhesion can be achieved without compromising electrical performance. Since high speed nets are typically routed in close proximity to one another, isolating high speed signaling region(s) or area(s) should not be too difficult. In addition, with multi-layer circuit boards, not all conductive layers will be signaling layers (e.g., ground layers) and not all signaling layers will include high speed nets. As such, the region(s) or area(s) of conductive material that remain smooth may be small compared to the region(s) or area(s) that are roughened.

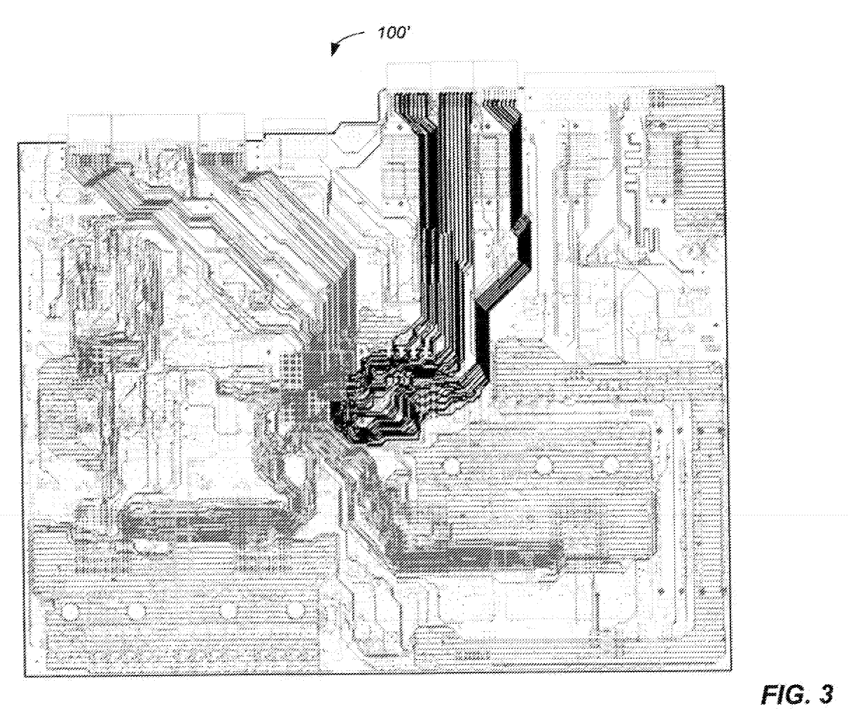

Shown in FIG. 3 is a modified version of sample circuit board 100 depicted in FIG. 1. Modified sample circuit board 100′ has selective surface roughness. In FIG. 3, high speed signal traces, which are shown as thicker lines, are smooth while remaining traces, which are shown as lighter gray lines, are rough.

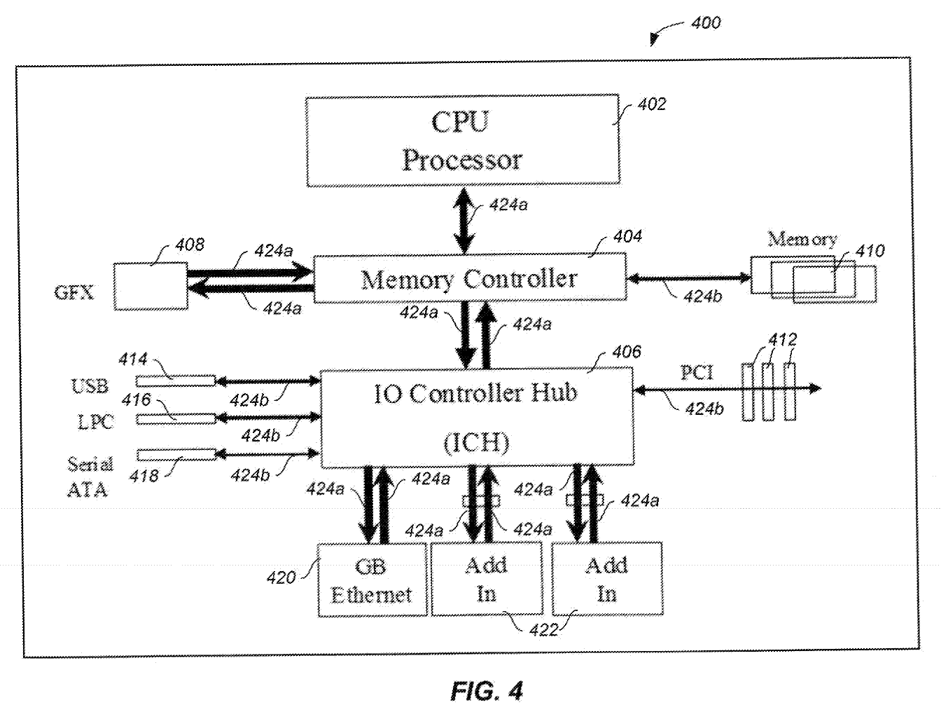

FIG. 4 depicts a top-down view of a circuit board 400 according to an implementation of the invention. Various components have been placed on circuit board 400, including a processor 402, a memory controller 404, an input/output (IO) controller hub 406, a graphics processor 408, memory modules 410, peripheral component interconnect (PCI) devices 412, a universal serial bus (USB) device 414, an low pin count (LPC) device 416, a serial advance technology attachment (ATA) device 418, a gigabyte (GB) Ethernet device 420, and two additional high speed device connectors 422. In FIG. 4, the various components are interconnected via traces 424 of circuit board 400. High speed traces 424a in the implementation are depicted with thicker lines, while non-high speed traces 424b are depicted with lighter lines.

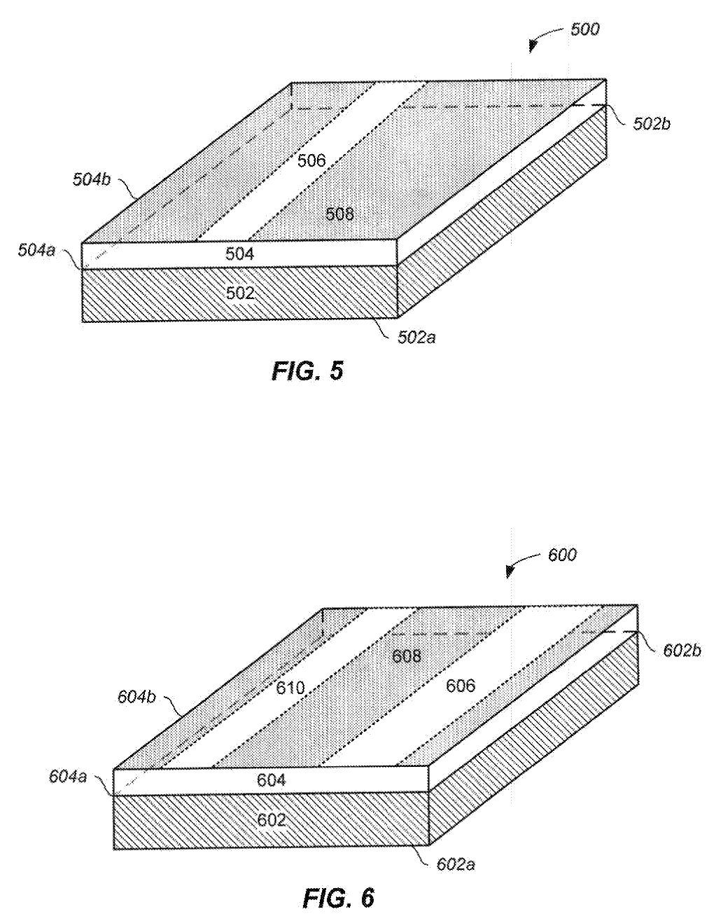

Illustrated in FIG. 5 is a circuit board 500 according to an implementation of the invention. Circuit board 500 includes a dielectric core 502 and a conductive layer 504. Dielectric core 502 includes a first surface 502a, which is on the bottom in the implementation, and a second surface 502b, which is beneath conductive layer 504. Conductive layer 504 also includes a first surface 504a, which is coupled to the second surface 502b of dielectric core 502, and a second surface 504b, which is on the top in the implementation.

Conductive layer 504 is a layer of copper foil in one implementation. A first region 506 of the second surface 504b of conductive layer 504 is smooth and a second region 508 of the second surface 504b of conductive layer 504, which encompasses the area outside of first region 506, is rough. Second region 508 is illustrated as a gray shaded area in FIG. 5. In the implementation, first region 506 of the second surface 504b of conductive layer 504 is operable to support high speed signaling (e.g., at or above 500 Mhz) and second region 508 of the second surface 504b of conductive layer 504 is operable to support non-high speed signaling.

FIG. 6 shows a circuit board 600 according to an implementation of the invention. Circuit board 600 includes a dielectric core 602 with a first surface 602a and a second surface 602b, and a conductive layer 604 with a first surface 604a and a second surface 604b. The first surface 604a of conductive layer 604 is coupled to the second surface 602b of dielectric core 602 through, for instance, lamination. As an example, conductive layer 604 may be rolled or electrically deposited on an adhesive applied to the second surface 602b of dielectric core 602.

A first region 606 and a third region 610 of the second surface 604b of conductive layer 604, which are operable to support high speed signaling, are smooth while a second region 608 of the second surface 604b of conductive layer 604, which is operable to support non-high speed signaling, is rough. Similar to FIG. 5, the rough region is shown as a gray shaded area in FIG. 6.

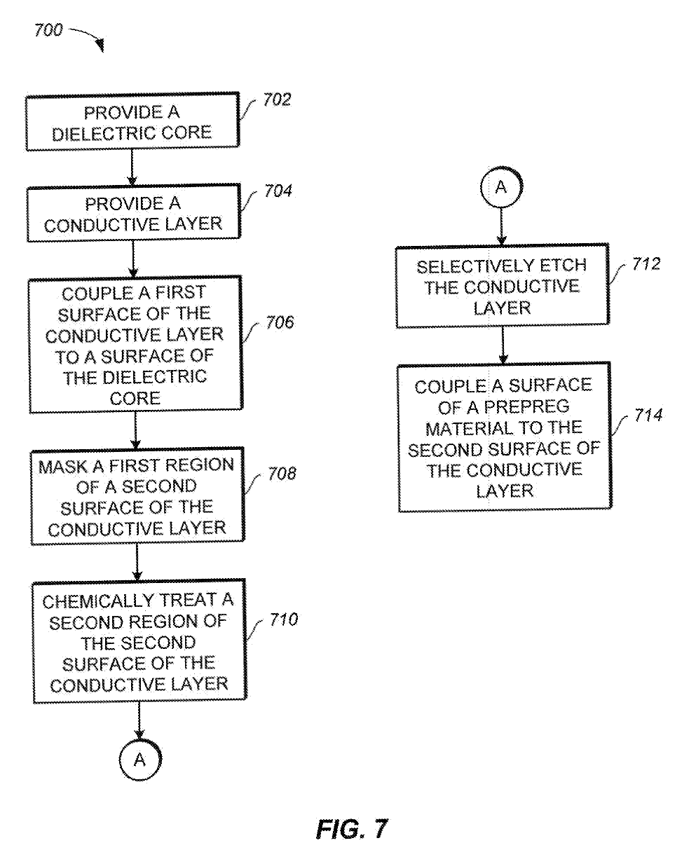

Depicted in FIG. 7 is a process 700 for fabricating a circuit board according to an implementation of the invention. At 702, a dielectric core is provided. A conductive layer is provided at 704. A first surface of the conductive layer is coupled to a surface of the dielectric core at 706. At 708, a first region of a second surface of the conductive layer is masked. At 710, a second region of the second surface of the conductive layer is chemically treated. The first region of the second surface of the conductive layer remains smooth as a result of the masking, while the second region of the second surface of the conductive layer is roughened as a result of the chemical treatment.

At 712, the conductive layer is selectively etched to form a plurality of circuit traces. A surface of a prepreg material is coupled to the second surface of the conductive layer at 714 through, for instance, lamination. The prepreg material may be an uncured fiberglass-epoxy resin and is available in different styles with varying amounts of resin and glass fibers. This allows manufacturers to control thickness between layers and thickness of a circuit board.

Although process 700 is described with reference to a particular ordering of process actions, the ordering may be changed without affecting the scope or operation of the invention. For example, chemical treatment of the second region of the second surface of the conductive layer can occur after etching of the conductive layer in another implementation.

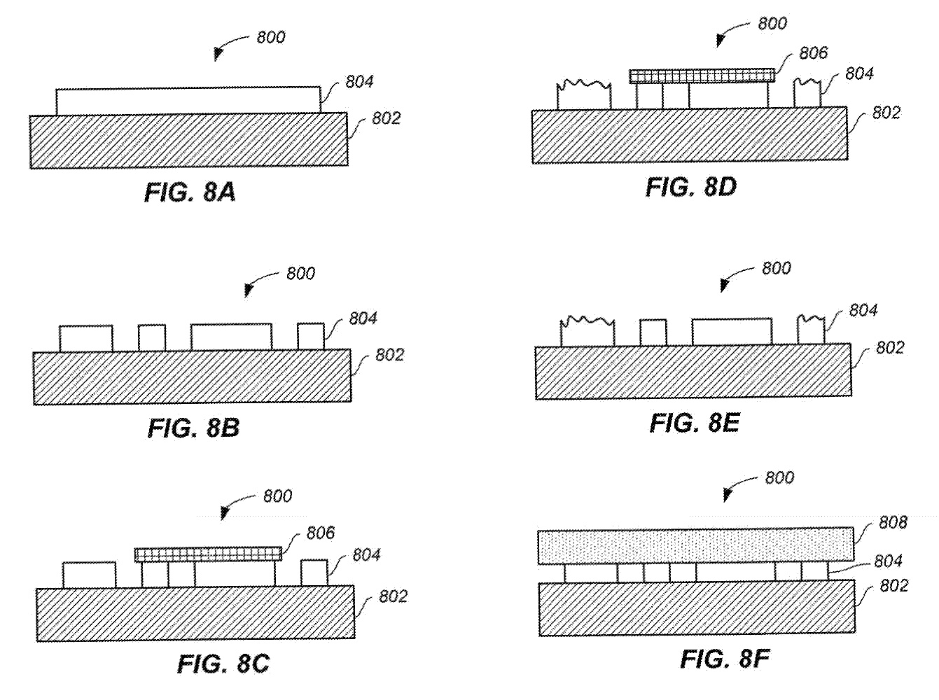

FIGS. 8A-8F illustrate cross-sectional views of a circuit board 800 at various stages during fabrication according to an implementation of the invention. As illustrated in FIG. 8A, a dielectric layer 802 has been provided and a conductive layer 804 has been coupled to dielectric layer 802. Selective areas of conductive layer 804 are then etched away to form circuit traces in FIG. 8B. A mask 806 is applied to a region of conductive layer 804 in FIG. 8C. In the implementation, the region is operable to support high speed signaling.

The surface of conductive layer 804 outside of the masked region is roughened in FIG. 8D. One way to roughen or treat the surface of a conductive layer is to form dendrites on the conductive layer surface. Another surface roughening treatment is to deposit nodules onto the surface of the conductive layer. The conductive layer surface may also be coated with zinc or brass to enhance adhesion.

In FIG. 8E, mask 806 is removed. A layer of prepreg material 808 is coupled to conductive layer 804 in FIG. 8F. Coupling between conductive layer 804 and prepreg material 808 can be accomplished through lamination. For example, dielectric core 802, conductive layer 804, and prepreg material 808 can be sandwiched between plates, then placed in a heated hydraulic press (e.g., 175° C. with 3000 kg of pressure) for a set period of time (e.g., 2 hours).

The degree to which the surface of conductive layer 804 is roughened can depend on the type of prepreg material 808 used. Once the required peel strength is achieved, further roughening of the surface will not serve any purpose. In addition, further roughening of the surface will increase manufacturing costs. Hence, the surface of conductive layer 804 should not be roughened any more than it is necessary.

Other steps may have been taken to fabricate circuit board 800, even though those steps are not illustrated in FIGS. 8A-8F. Some examples of other steps that may have been taken include coating of dielectric core 802 to prepare it for coupling to conductive layer 804, cleaning of dielectric core 802 via a mechanical or a chemical process to remove surface contamination, and placement of a photoresist layer on conductive layer 804.

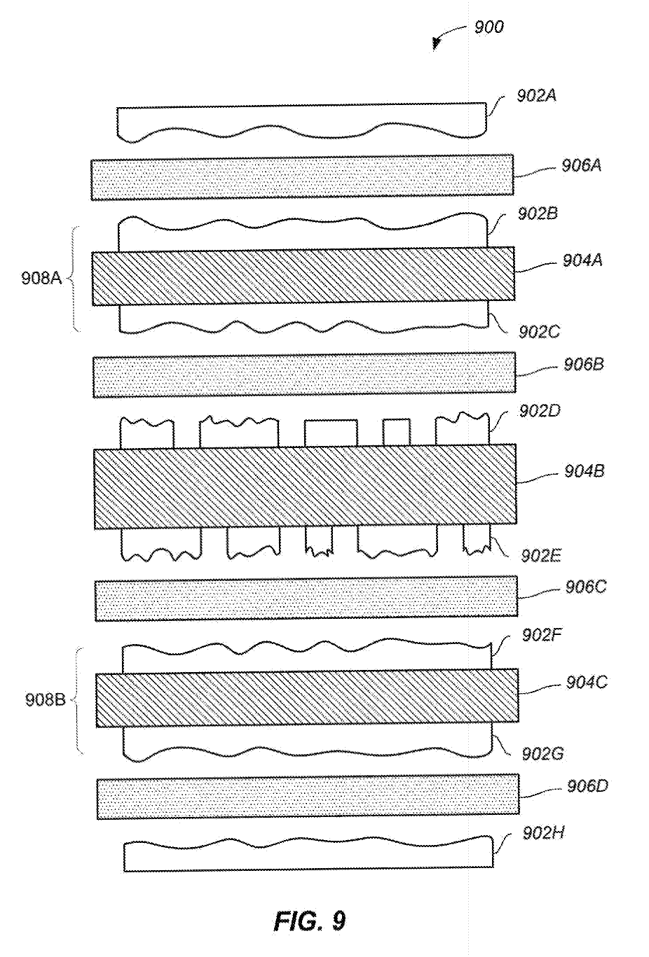

Shown in FIG. 9 is a cross-sectional view of various layers of a circuit board 900 according to an implementation of the invention. Circuit board 900 includes eight conductive layers 902A-902H, three dielectric cores 904A-904C, and four layers of prepreg material 906A-906D. In the implementation, stack-up of the various layers of circuit board 900 is symmetric about the center of the vertical axis to avoid mechanical stress in the board.

As shown in FIG. 9, conductive layers 902D and 902E are signal layers, i.e., circuit traces have been formed therein through, for instance, etching. Conductive layers 902A and 902H can be etched after being coupled to prepreg material 906A and 906D, respectively, to transform conductive layers 902A and 902H into signal layers. Conductive layers 902B, 902C, 902F, and 902G are dedicated supply layers, also called ground layers.

In the implementation, only the surface conductive layer 902D has been selectively roughened because, as previously noted, not all conductive layers in a circuit board are signal layers and not all signal layers include traces for high speed signaling. Signal layer 902E, which does not include any high speed nets, and ground layers 902B-902C and 902F-902G have been uniformly roughened. Additionally, a surface of conductive layer 902A facing prepreg material 906A and a surface of conductively layer 902H facing prepreg material 906D have been uniformly roughened since those surfaces will not be used for signaling.

Circuit board 900 also includes power planes 908A and 908B, which have thinner dielectric cores 904A and 904C to maximize capacitance between the planes. Ground planes (not shown) can also have thinner dielectric cores for similar reasons. Thicker conductive layers 902B-902C and 902F-902G may be used to reduce resistance. Power planes 908A and 908B provide a stable reference voltage for signals, distribute power to all devices, and control cross-talk between signals.

While various circuit board implementations and implementations for fabricating a circuit board have been described, the technical scope of the present invention is not limited thereto. It is to be understood by those skilled in the art that various modifications or improvements can be added to the above implementations. It is apparent from the appended claims that such modified or improved implementations fall within the technical scope of the present invention.

What is claimed is:

1. A circuit board comprising:
a dielectric core comprising a first surface and a second surface; and
a first conductive layer comprising a first surface and a second surface, the first surface of the first conductive layer being coupled to the second surface of the dielectric core,
wherein a first region of the second surface of the first conductive layer is smooth and a second region of the second surface of the first conductive layer is rough,
the first region of the second surface of the first conductive layer being operable to support high speed signaling and the second region of the second surface of the first conductive layer being operable to support non-high speed signaling.

2. The circuit board of claim 1, wherein high speed signaling is signaling at or above 500 Megahertz.

3. The circuit board of claim 1, wherein the first conductive layer comprises a layer of copper foil.

4. The circuit board of claim 1, wherein the first conductive layer comprises a plurality of circuit traces.

5. The circuit board of claim 1, wherein a third region of the second surface of the first conductive layer is smooth, the third region of the second surface of the first conductive layer being operable to support high speed signaling.

6. The circuit board of claim 1, further comprising:
a prepreg material comprising a first surface and a second surface, wherein the first surface of the prepreg material is coupled to the second surface of the first conductive layer.

7. The circuit board of claim 6, further comprising:
a second conductive layer comprising a first surface and a second surface, wherein the first surface of the second conductive layer is coupled to the second surface of the prepreg material.

8. The circuit board of claim 7, wherein a first region of the second surface of the second conductive layer is smooth and a second region of the second surface of the second conductive layer is rough, the first region of the second surface of the second conductive layer being operable to support high speed signaling and the second region of the second surface of the second conductive layer being operable to support non-high speed signaling.

9. The circuit board of claim 1, further comprising:
a third conductive layer comprising a first surface and a second surface, wherein the second surface of the third conductive layer is coupled to the first surface of the dielectric core.

10. The circuit board of claim 9, wherein a first region of the first surface of the third conductive layer is smooth and a second region of the first surface of the third conductive layer is rough, the first region of the first surface of the third conductive layer being operable to support high speed signaling and the second region of the first surface of the third conductive layer being operable to support non-high speed signaling.

11. A method for fabricating a circuit board, the method comprising:
providing a dielectric core comprising a first surface and a second surface;
providing a first conductive layer comprising a first surface and a second surface, the second surface of the first conductive layer being smooth;
coupling the first surface of the first conductive layer to the second surface of the dielectric core;
masking a first region of the second surface of the first conductive layer; and
roughening a second region of the second surface of the first conductive layer,
wherein the first region of the second surface of the first conductive layer remains smooth,
the first region of the second surface of the first conductive layer being operable to support high speed signaling and the second region of the second surface of the first conductive layer being operable to support non-high speed signaling.

12. The method of claim 11, wherein high speed signaling is signaling at or above 500 Megahertz.

13. The method of claim 11, wherein roughening the second region of the second surface of the first conductive layer comprises:
chemically treating the second region of the second surface of the first conductive layer.

14. The method of claim 11, further comprising:
selectively etching the first conductive layer to form a plurality of circuit traces.

15. The method of claim 11, further comprising:
masking a third region of the second surface of the first conductive layer,
wherein the third region of the second surface of the first conductive layer remains smooth,
the third region of the second surface of the first conductive layer being operable to support high speed signaling.

16. The method of claim 11, further comprising:
providing a prepreg material comprising a first surface and a second surface; and
coupling the first surface of the prepreg material to the second surface of the first conductive layer.

17. The method of claim 16, further comprising:
providing a second conductive layer comprising a first surface and a second surface, the second surface of the second conductive layer being smooth;
coupling the first surface of the second conductive layer to the second surface of the prepreg material;
masking a first region of the second surface of the second conductive layer; and
roughening a second region of the second surface of the second conductive layer,
wherein the first region of the second surface of the second conductive layer remains smooth,
the first region of the second surface of the second conductive layer being operable to support high speed signaling and the second region of the second surface of the second conductive layer being operable to support non-high speed signaling.

18. The method of claim 11, further comprising:
providing a third conductive layer comprising a first surface and a second surface, the first surface of the third conductive layer being smooth;
coupling the second surface of the third conductive layer to the first surface of the dielectric core;
masking a first region of the first surface of the third conductive layer; and
roughening a second region of the first surface of the third conductive layer,
wherein the first region of the first surface of the third conductive layer remains smooth,
the first region of the first surface of the third conductive layer being operable to support high speed signaling and the second region of the first surface of the third conductive layer being operable to support non-high speed signaling.
